(19) United States
(12) Patent Application Publication
(10) Pub. No.: US 2008/0093709 A1
(43) Pub. Date: Apr. 24, 2008

(54) Manufacturing method of semiconductor device and semiconductor device

(75) Inventors: Masazumi Matsuura, Tokyo (JP); Kinya Goto, Tokyo (JP); Hisashi Yano, Kyoto (JP); Kotaro Nomura, Osaka (JP)

Correspondence Address: MCDERMOTT WILL & EMERY LLP, 600 13TH STREET, N.W., WASHINGTON, DC, 20005-3096, US

(73) Assignees: RENESAS TECHNOLOGY CORP.; MATSUSHITA ELECTRIC INDUSTRIAL CO., LTD

(21) Appl. No.: 11/907,998

(22) Filed: Oct. 19, 2007

(30) Foreign Application Priority Data
Oct. 20, 2006 (JP) JP2006-285808

(51) Int. Cl. H01L 21/42; H01L 23/58

(52) U.S. Cl. 257/632; 438/795; 257/E21.471; 257/E23.002

(57) ABSTRACT

A semiconductor substrate in a state that an inter-layer insulation film is formed is loaded in a chamber, air in the chamber is purged by introducing a large amount of a nitrogen gas in the chamber, and an atmospheric gas in the chamber is substituted with a nitrogen gas. After that, UV cure is performed by introducing a small amount of an oxygen gas adjusted to an atmospheric pressure or a little more positive pressure in the chamber by nitrogen purge. For the introduction of an oxygen gas, an oxygen gas is introduced while controlling the flow rate by using a flow meter, and adjustment is performed using the flow meter so that the oxygen concentration in the chamber becomes a constant value in the range of 5 ppm to 400 ppm.

### BACKGROUND OF THE INVENTION

1. Field of the Invention

The present invention relates to a manufacturing method of a semiconductor device and a semiconductor device, and especially relates to a manufacturing method of a semiconductor device cured by irradiation with ultraviolet rays (a UV cure process) and a semiconductor device obtained with the manufacturing method.

2. Description of the Background Art

In a system LSI (Large Scale Integration) system, an increase in wiring delay becomes a problem as microfabrication progresses. Because a wiring delay is proportional to the product of the wire resistance and the parasitic capacitance of the wiring, a method of reducing the parasitic capacitance has been adopted popularly using an insulation film with a low dielectric constant (a low-k film) as an inter-layer insulation film together with using copper having a low resistance as the wiring.

However, because the mechanical strength of the low-k film decreases as the dielectric constant gets lower, there is a possibility that a crack is generated in the inter-layer insulation film or that the inter-layer insulation film is stripped in a step in which a large stress is generated in the semiconductor manufacturing steps such as a chemical mechanical polishing (CMP) step and a packaging step, for example.

A UV cure technique has attracted attention in which annealing is performed at a high temperature while applying ultraviolet rays (UV: Ultra Violet) to address the decrease of the mechanical strength of the low-k film.

For example, Japanese Patent Application Laid-Open No. 2004-274052 discloses a technique in which the hardness of the low-k film is improved by 10% to 25% by performing the UV cure in a non-oxidized atmosphere, Japanese translation of PCT International Application No. 2005-503672 discloses a technique in which the modulus of elasticity is improved by curing the low-k film by exposing to microwave plasma, and then exposing to ultraviolet rays in a gas such as oxygen, nitrogen, or argon, and Japanese translation of PCT International Application No. 2005-503673 discloses a technique in which the modulus of elasticity is improved by exposing the low-k film to ultraviolet rays in a gas such as oxygen, nitrogen, or argon.

As explained above, the UV cure is considered to be a useful method to address the decrease of the mechanical strength of the low-k film. However, in any of the above-described documents, the process condition is set broadly and vague. Especially, the component ratio etc. of the atmospheric gas in the reaction chamber where the UV cure is performed is not disclosed specifically, and there is a question whether the mechanical strength of the low-k film can be practically improved or not only with the disclosures of these documents.

### SUMMARY OF THE INVENTION

The objective is to provide a specific manufacturing method to improve the mechanical strength of a low-k film by focusing on the atmospheric gas in the chamber in which the UV cure is performed.

The mode of the manufacturing method of a semiconductor device according to the present invention is a manufacturing method of a semiconductor device having at least one layer of an SiOC film as an inter-layer insulation film, including a step (a) of performing a first curing by irradiation with ultraviolet rays the above-described SiOC film after formation of the above-described SiOC film, in which the above-described first curing is performed in a condition in which oxygen is included so that the oxygen concentration is 5 ppm to 400 ppm in the atmosphere of a chamber in which the first curing is performed.

According to the above-described manufacturing method, by performing the first curing in a condition in which oxygen is included so that the oxygen concentration is 5 ppm to 400 ppm in the atmosphere of the chamber in which the first curing is performed, a 3-membered ring Si—O bond and an Si—H bond are not produced, and on the other hand, the network of Si—O bonds increase, and the mechanical strength of the SiOC film can be improved without spoiling resistance to process damage.

The mode of the semiconductor device according the present invention is a semiconductor device having at least one layer of an SiOC film as an inter-layer insulation film, in which the concentration of hydrogen in the SiOC film is less than 1×10²⁰ atoms/cc.

According to the above-described semiconductor device, because the concentration of hydrogen in the SiOC film is less than 1×10²⁰ atoms/cc, a semiconductor device can be obtained in which there are few unstable Si—H bonds in the network of Si—O bonds, promotion of process damage to the SiOC film from an etching step, a resist ashing step, and a cleaning step is prevented, the mechanical strength of the inter-layer insulation film is good, and cracking and stripping of the inter-layer insulation film are prevented.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 10 are sectional views illustrating the manufacturing steps of the semiconductor device in an embodiment of the present invention;

FIG. 11 is a figure showing a structure of the 3-membered ring Si—O bond;

FIG. 12 is a figure showing a part of a structure of the network of Si—O bonds;

FIG. 13 is a figure showing a differential spectrum of the FT-IR spectra before and after the UV cure;

FIG. 14 is a figure showing the change of the specific dielectric constant of the SiOC film on which the resist ashing and cleaning are performed;

FIG. 15 is a figure showing a differential spectrum of the FT-IR spectrum in the case of varying the oxygen concentration; and

FIG. 16 is a figure schematically showing a damage layer on the surface of the low-k film formed by plasma.

### DESCRIPTION OF THE PREFERRED EMBODIMENTS

### A. Embodiment

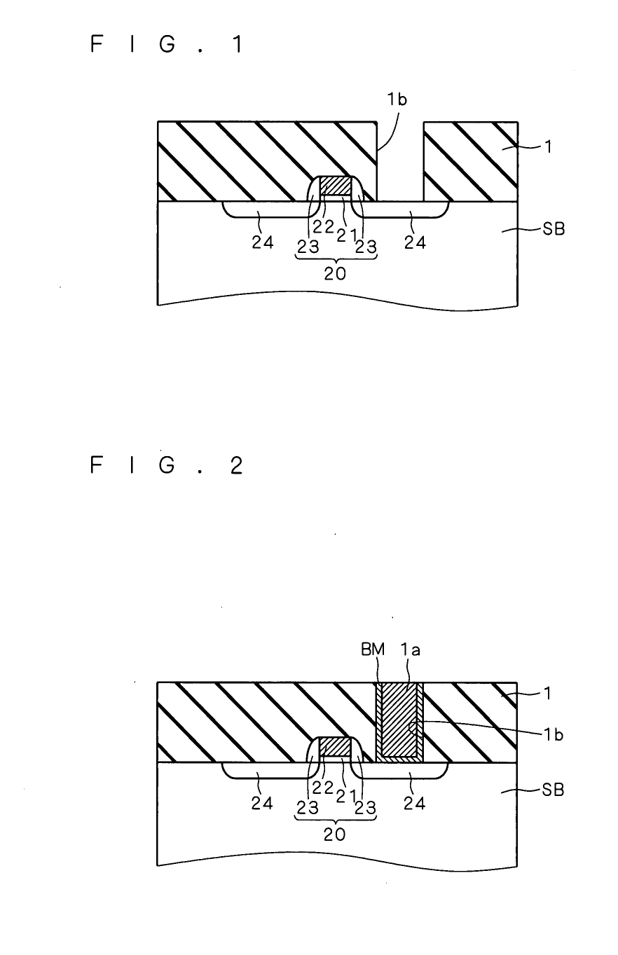

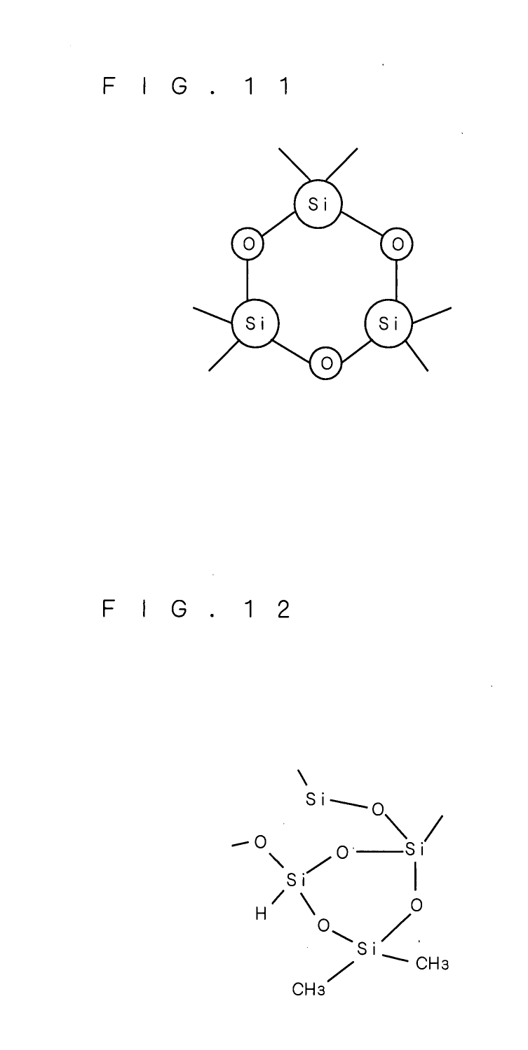

The manufacturing method of a semiconductor device 100 in an embodiment of the present invention is explained using FIGS. 1 to 10 showing the manufacturing steps in order. Moreover, a configuration of the semiconductor device 100 is shown in FIG. 10 illustrating the final step.

### A-1. Manufacturing Steps

First, in the step shown in FIG. 1, a semiconductor substrate SB such as a silicon substrate is prepared, and a semiconductor integrated circuit is formed on the semiconductor substrate SB.

A MOS transistor 20 is shown in FIG. 1 as one example of a semiconductor element configuring the semiconductor integrated circuit.

The MOS transistor 20 is configured with a gate electrode 22 provided on a semiconductor substrate 1 through a gate insulation film 21, a side-wall insulation film 23 provided on the side face of the gate electrode 22, and source and drain layers 24 each provided in the surface of the semiconductor substrate SB outside of both side faces in the gate length direction of the gate electrode 22.

Moreover, because the semiconductor integrated circuit containing the MOS transistor 20 is formed with a known technique, the explanation of the manufacturing method in omitted.

Next, an under-layer insulation film 1 having a thickness of 300 to 500 nm covering the semiconductor integrated circuit is provided by forming a silicon oxide film on the entire surface of the semiconductor substrate SB with a CVD (Chemical Vapor Deposition) method, for example.

After that, an opening part 1b is provided reaching to the source and drain layers 24 of the MOS transistor 20 by boring through the under-layer insulation film 1 with anisotropic etching.

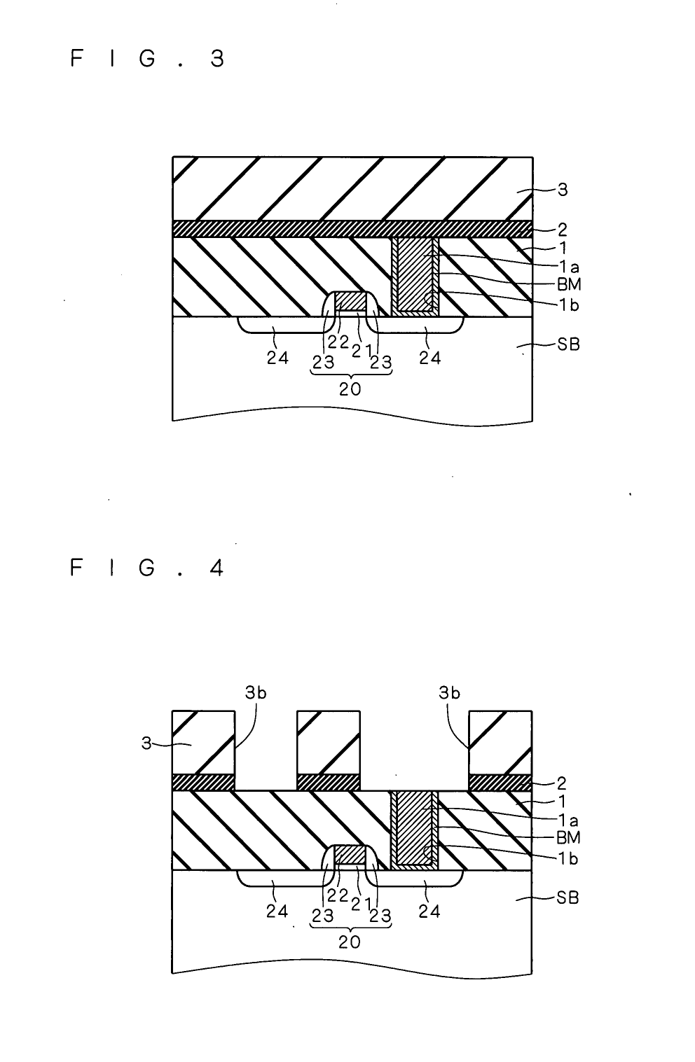

Next, in the step shown in FIG. 2, a contact part 1a is formed by providing a barrier metal layer BM on the inner face of the opening part 1b by forming a TiN (titanium nitride) film or a Ti (titanium) film to cover the inner face of the opening part 1b as well as to cover the entire face of the under-layer insulation film 1 with a sputtering method, filling the opening part 1b with tungsten (W) using a CVD method, and then removing the unnecessary barrier metal layer BM and tungsten using a CMP (Chemical Mechanical Polishing) method.

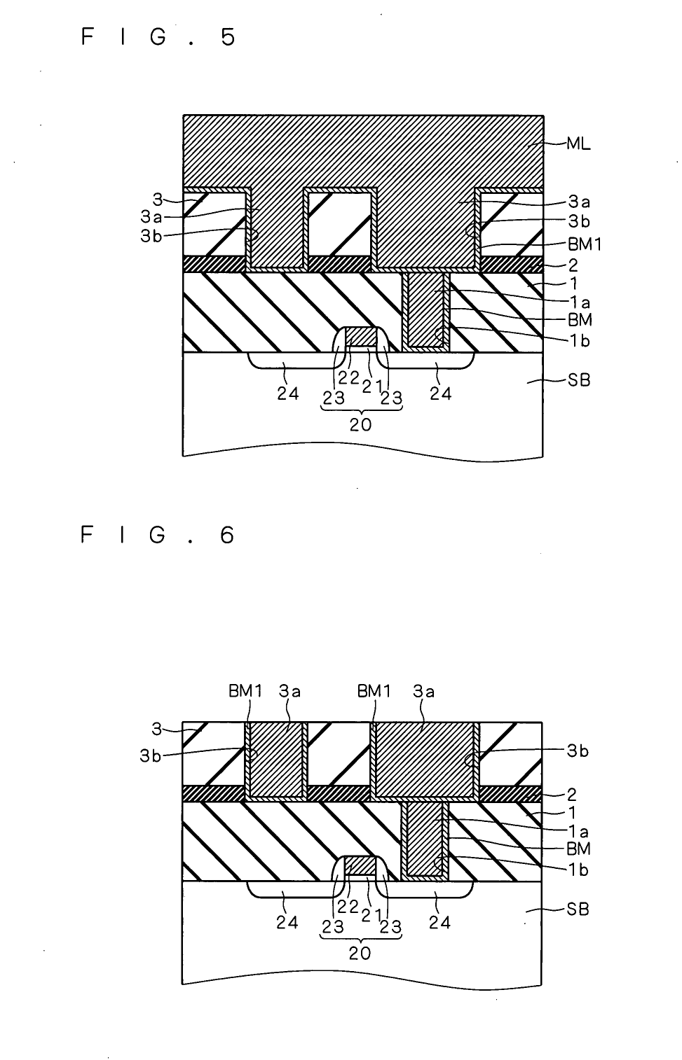

Next, in a step shown in FIG. 3, an inter-layer insulation film 2 having a thickness of about 50 nm is formed on the entire surface of the under-layer insulation film 1 with a plasma CVD method, for example. The material of the inter-layer insulation film 2 may be selected from a silicon carbide film (an SiC film), a silicon nitride film (an SiN film), an SiCN film in which nitrogen is added to the SiC film, and an SiCO film in which oxygen is added to the SiC film.

Next, an inter-layer insulation film 3 (a first low-k film) having a thickness of about 100 nm is provided by forming an SiOC film, that is a silicon oxide film in which carbon is added, having a specific dielectric constant of 2.3 to 3.0 on the entire surface of the inter-layer insulation film 2 with a plasma CVD method, for example.

Moreover, the dielectric constant of the SiOC film formed with a plasma CVD method can be changed from 2.0 to 3.5 with good controllability with a process condition (types and flow rate of gas, high frequency power, gas pressure, wafer temperature, etc.) of the plasma CVD method. However, the process condition is set in the present embodiment so that the specific dielectric constant becomes any of specific dielectric constants in the range of 2.3 to 3.0.

An MSQ (Methylsilisesquioxane) film having the same film composition and molecular structure as the SiOC film can be applied to the inter-layer insulation film 2 similarly to the SiOC film.

The MSQ film is formed with a coating method called a spin-on method, similar to the SiOC film in composition, and the specific dielectric constant can be changed from 2.0 to 3.4 with good controllability similarly to the SiOC film by changing the molecular weight of the raw material polymer of the coating material. Moreover, because there exist pores in the MSQ film having a specific dielectric constant of 2.5 or less, there is a case that the film is particularly referred to as a porous MSQ film.

After forming the inter-layer insulation film 3, the mechanical strength of the SiOC film is improved by carrying out a UV cure process (a first curing) according to the present invention to the inter-layer insulation film 3. Moreover, a process condition of the UV cure process is explained later.

Next, in a step shown in FIG. 4, a plurality of groove-shaped opening parts 3b are formed reaching the under-layer insulation film 1 by penetrating through the inter-layer insulation films 2 and 3 with anisotropic etching. Among the opening parts 3b, there are opening parts provided to reach the contact part 1a.

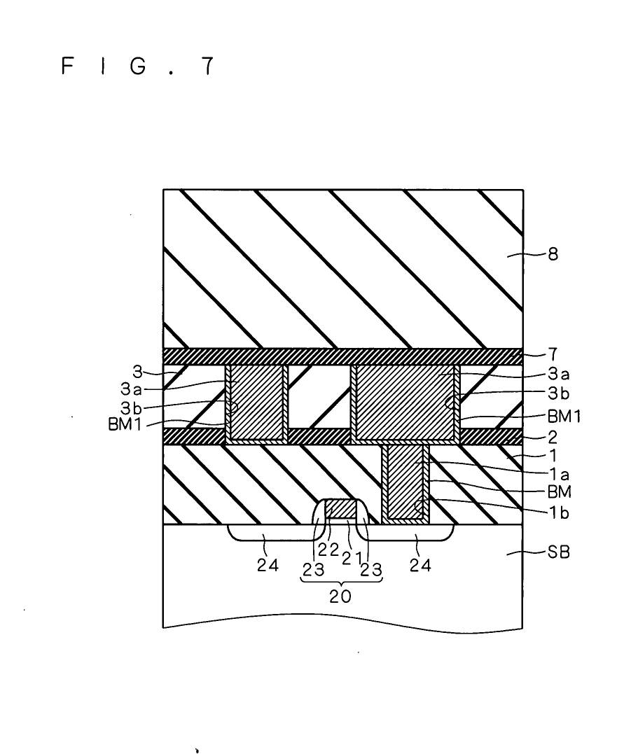

After that, in a step shown in FIG. 5, a barrier metal layer BM1 is provided by forming a TaN (tantalum nitride) film or a Ta film to cover the inner face of the opening part 3b as well as to cover the entire face of the inter-layer insulation film 3 with a sputtering method, a Cu seed film is provided to cover the entire face of the barrier metal layer BM1 with a sputtering method, and a Cu film ML is filled in the opening parts 3b of which the inner face is covered with the barrier metal layer BM1 by forming a Cu film ML with a plating method using the Cu seed film as an electrode.

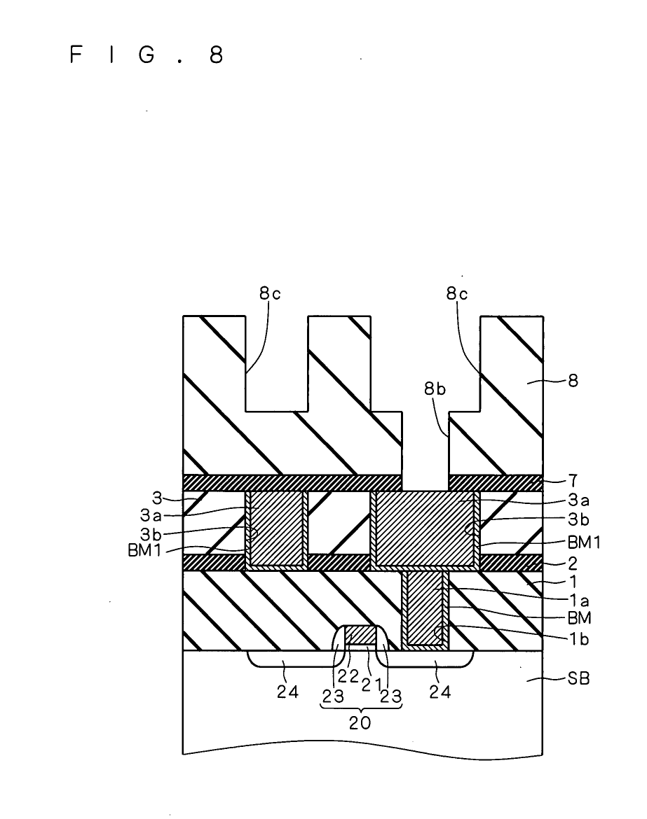

After that, the barrier metal layer BM1 and a wiring layer 3a (a first wiring layer) as shown in FIG. 6 are obtained by removing the unnecessary Cu film ML and the barrier metal layer BM1 on the inter-layer insulation film 3 using a CMP method.

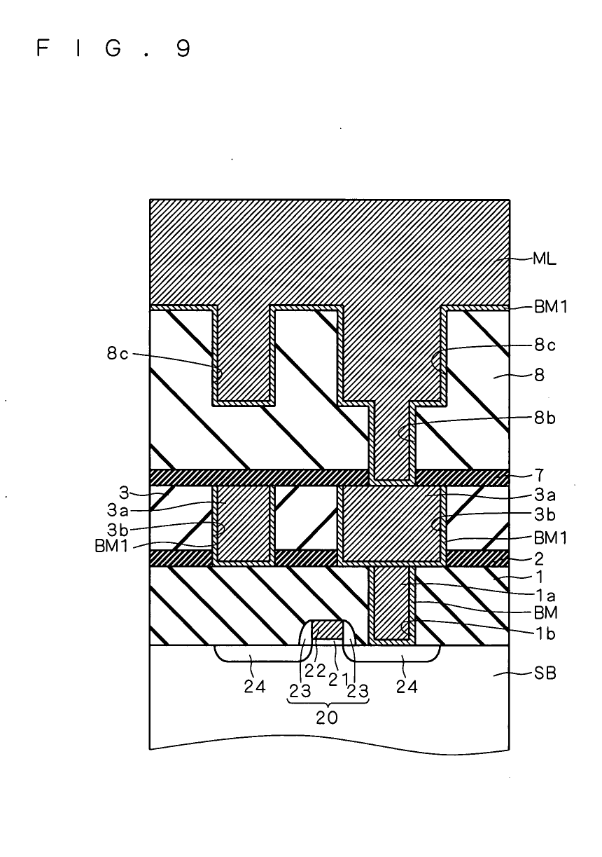

Next, in a step shown in FIG. 7, an inter-layer insulation film 7 having a thickness of about 50 nm is formed on the entire face of the inter-layer insulation film 3 including the top of the wiring layer 3a with a plasma CVD method, for example. The material of the inter-layer insulation film 7 may be selected from an SiC film, a silicon nitride film (an SiN film), an SiCN film, and an SiCO film.

Next, an inter-layer insulation film 8 (a second low-k film) having a thickness of about 250 nm is provided by forming an SiOC film having a specific dielectric constant of 2.3 to 3.0 on the entire face of the inter-layer insulation film 7 with a plasma CVD method, for example. Moreover, an MSQ film may be formed with a spin-on method instead of the SiOC film.

After forming the inter-layer insulation film 8, the mechanical strength of the SiOC film is improved by carrying out a UV cure process (a first curing) according to the present invention to the inter-layer insulation film 8. Moreover, a process condition of the UV cure process is explained later.

Next, in a step shown in FIG. 8, a plurality of groove-shaped opening parts 8c are formed in the top layer part of the inter-layer insulation film 8 and also a hole-shaped opening part 8b reaching the wiring layer 3a are formed by penetrating the inter-layer insulation films 8 and 7 with anisotropic etching. At least one of the plurality of opening parts 8c is provided so that it communicates with the opening part 8b.

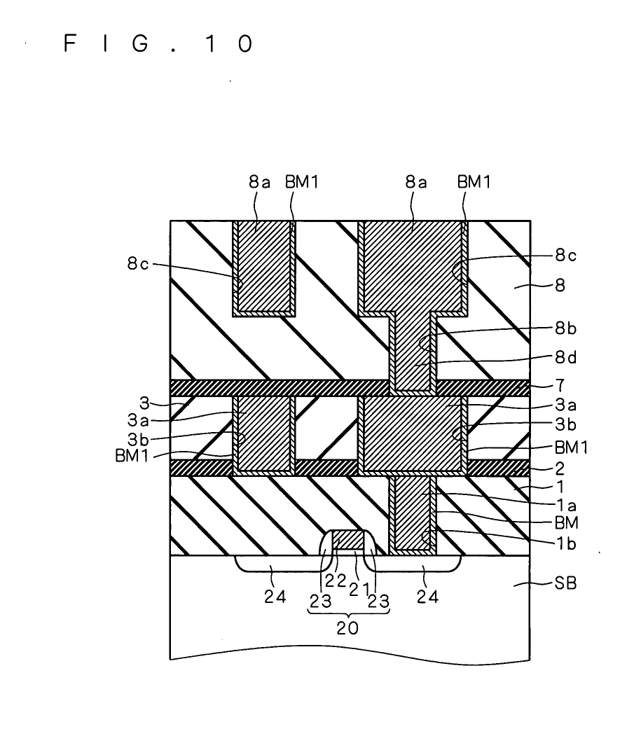

Next, in a step shown in FIG. 9, a barrier metal layer BM1 is provided by forming a TaN film or a Ta film to cover the inner face of the opening parts 8b and 8c as well as to cover the entire face of the inter-layer insulation film 8 with a sputtering method, a Cu seed film is provided to cover the entire face of the barrier metal layer BM1 with a sputtering method, and a Cu film ML is filled in the opening parts 8b and 8c of which the inner face is covered with the barrier metal layer BM1 by forming a Cu film ML with a plating method using the Cu seed film as an electrode.

After that, the barrier metal layer BM1 and a wiring layer 8a (a second wiring layer) as shown in FIG. 10 are obtained by removing the unnecessary Cu film ML and the barrier metal layer BM1 on the inter-layer insulation film 8 using a CMP method. Moreover, a contact part 8d is provided in the opening part 8b.

### A-2. UV Cure Process

Next, the UV cure process according to the present invention is explained in detail.

A technique of performing UV cure in a non-oxidized atmosphere is shown in Japanese Patent Application Laid-Open No. 2004-274052 explained above, and oxygen is considered to be harmful conventionally in the UV cure.

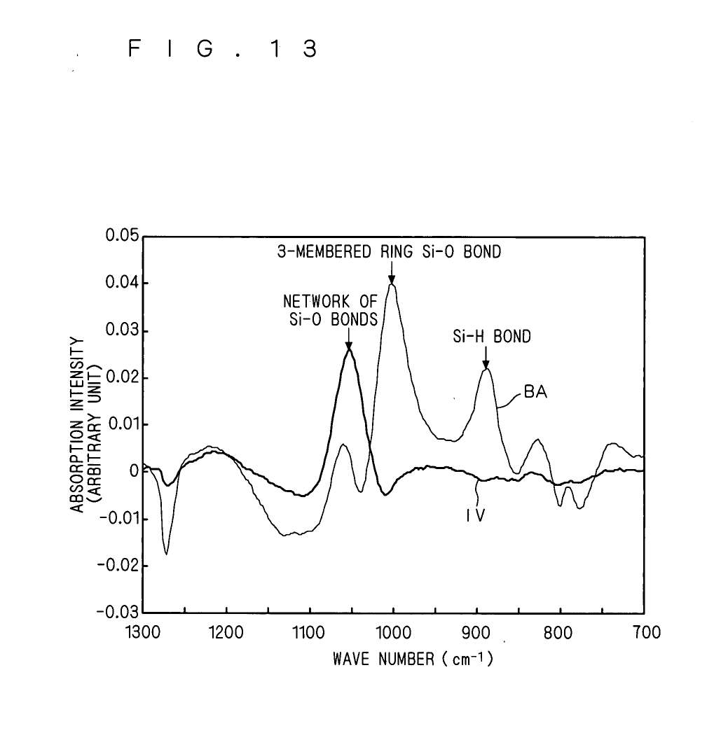

However, it is confirmed in an experiment by the present inventors that a 3-membered ring Si—O bond shown in FIG. 11 and an Si—H bond shown in FIG. 12 are produced when UV cure is carried out on an SiOC film in such a non-oxidized atmosphere.

Here, FIG. 12 is a figure showing a part of a structure of a network of Si—O bonds, and the network of Si—O bonds also has an S₁—CH₃ bond other than the 3-membered ring Si—O bond and the Si—H bond.

Such a change of the structure is observed with an FT-IR method (a Fourier transform infrared spectroscopy method).

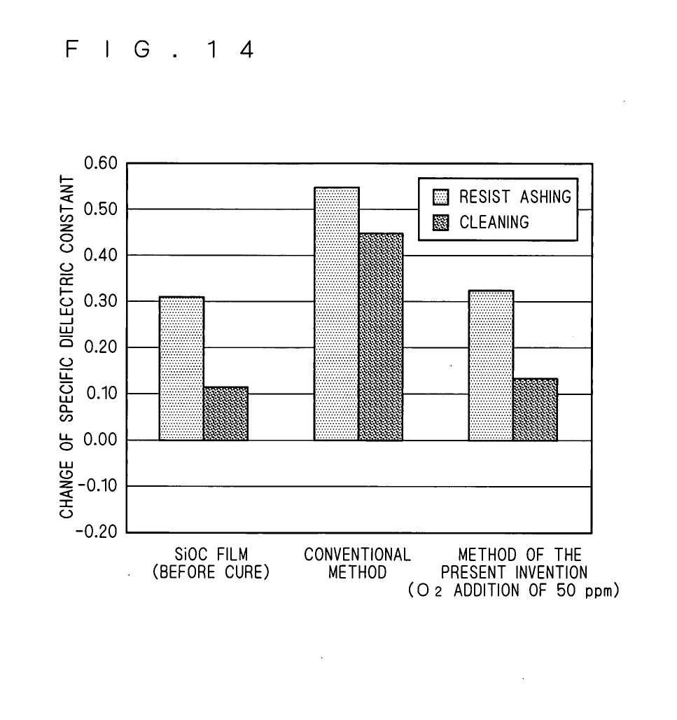

Here, differential spectra of the FT-IR spectrum before and after the UV cure are shown in FIG. 13. In FIG. 13, a wave number (cm⁻¹) that is the reciprocal of the wavelength is shown in the x-axis and absorption intensity (an arbitrary unit) of the infrared light is shown in the y-axis, and a differential spectrum BA obtained with the conventional UV cure and a differential spectrum IV obtained with the UV cure according to the present invention are shown.

The wave number corresponds to the infrared energy that is absorbed, and the type of the bond can be known from the wave number corresponding to a peak of the spectrum.

A rising peak in a positive direction of the differential spectrum shows a peak caused by a bond increasing after the UV cure, and 3-membered ring Si—O bonds and Si—H bonds increase after the UV cure in the conventional UV cure as can bee understood from FIG. 13.

The 3-membered ring Si—O bond and the Si—H bond are in an unstable bonding state in the network of Si—O bonds, and they have a characteristic to produce an Si—OH bond by reacting with an oxygen radical excited by H₂O (water) in the atmosphere or plasma, and to become a stable state.

Therefore, it can be considered that process damage that the SiOC film on which the UV cure is performed receives from an etching step, a resist ashing step, and a cleaning step is promoted by an increase of the 3-membered ring Si—O bond and the Si—H bond.

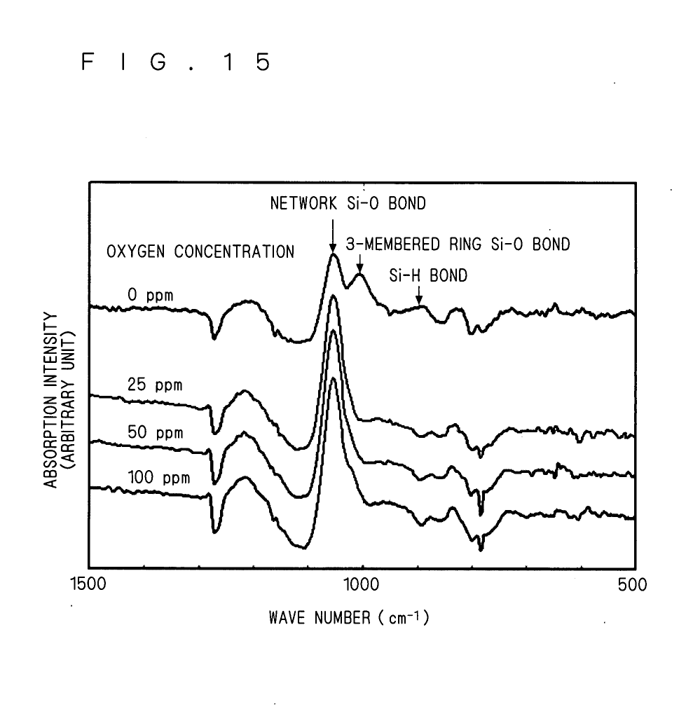

FIG. 14 shows the change of the specific dielectric constant of the SiOC film on which resist ashing and cleaning are carried out for an SiOC film before cure, an SiOC film that has already been UV cured with a conventional method, and an SiOC film that has already been UV cured according to the present invention.

It is shown in FIG. 14 that the specific dielectric constant of the SiOC film that has already been UV cured with the conventional method has increased drastically in any cases by carrying-out the resist ashing and the cleaning, and it is considered that the SiOC film in which the 3-membered ring Si—O bond and the Si—H bond are produced in the film by the UV cure has become easier to receive process damage from the resist ashing and the cleaning steps than the SiOC film in which the UV cure is not performed. Moreover, because a low-k film that has received process damage changes into a film with a quality of high absorbency, an unpreferable condition, that is an increase of the specific dielectric constant, is brought about.

The present inventors reached a technical idea that adding a small amount of oxygen in the atmosphere gas in the chamber in which the UV cure is carried out is effective in order to suppress the production of the 3-membered ring Si—O bond and the Si—H bond.

In the UV cure process of the present invention, a semiconductor substrate SB (FIG. 3) in the state that the inter-layer insulation film 3 is formed and a semiconductor substrate SB (FIG. 7) in the state that the inter-layer insulation film 8 is formed are housed in the chamber in which the UV cure is carried out, and the atmosphere gas in the chamber is substituted to a nitrogen gas by introducing a large amount of the nitrogen gas in the chamber and purging air in the chamber.

After that, the UV cure is carried out by introducing a small amount of an oxygen gas in the chamber adjusted to an atmospheric pressure or a little more positive pressure than the atmospheric pressure with the nitrogen purge. With this operation, an impurity gas other than the oxygen gas is prevented from entering the chamber.

When the oxygen gas is introduced, the oxygen gas is introduced while controlling the flow rate using a flow meter, the oxygen concentration is monitored with an oxygen concentration meter provided in the chamber, and in the case that a fixed concentration is achieved, the introduction of the oxygen gas is stopped.

In such a manner, by introducing the oxygen gas while controlling the flow rate in the chamber, the oxygen gas can be added easily in the case that oxygen is consumed as UV cure proceeds and the oxygen concentration is lowered.

Here, the adjustment is performed using the flow meter so that the concentration of oxygen in the UV chamber becomes a constant value in the range of 5 ppm to 400 ppm, more desirably in the range of 25 ppm to 100 ppm throughout the entire UV cure process.

When it is in the range of 25 ppm to 100 ppm, there is an advantage that control of the gas flow rate is easy.

Further, in the present embodiment, a mercury lamp having a wavelength band of 200 nm to 600 nm is used for the UV lamp, and the wafer temperature at the time of UV cure is set in the range of 300° C. to 450° C.

The process condition of the UV cure process used in the present embodiment is shown in Table 1.

TABLE 1

| Process condition | Set value |
|---|---|
| UV lamp wavelength | 200 nm~600 nm |
| UV chamber pressure | Atmospheric pressure (nitrogen |
| | purge) |
| Addition amount of oxygen | 25 ppm~100 ppm |
| Wafer temperature | 300° C.~450° C. |

### A-3. Action and Effect

The differential spectrum IV shown in FIG. 13 shows a differential spectrum of the FT-IR spectrum of the SiOC film in the case of controlling the amount of introduced oxygen so that the oxygen concentration in the chamber becomes 50 ppm and performing a UV cure process at a wafer temperature of 375° C.

It is understood from FIG. 13 that the production of the 3-membered ring Si—O bond and the Si—H bond is not seen with the UV cure condition of the oxygen concentration of 50 ppm, and that the network of Si—O bonds increases on the other hand, and an ideal change is occurring in order to improve the mechanical strength.

Further, the SiOC film that has already been Lw cured according to the present invention shown in FIG. 14 shows a characteristic of the SiOC film in the case of controlling the amount of introduced oxygen so that the oxygen concentration in the chamber becomes 50 ppm and performing a UV cure process at a wafer temperature of 375° C., and the amount of process damage, that is, the changing amount of the specific dielectric constant, is almost the same as the SiOC film that has not been Lw cured, and an increase of process damage (an increase of the changing amount of the specific dielectric constant) is not seen.

The reason for this is considered that a small amount of oxygen introduced into the chamber makes the decomposition of the Si—CH₃ group (FIG. 12) in the SiOC film easy and promotes an Si—O—Si crosslinking reaction.

From the above result, a conclusion is reached in which the mechanical strength of the SiOC film can be improved without spoiling process damage resistance by performing the Lw cure process on the SiOC film in the UV cure condition of an oxygen concentration of 50 ppm.

Moreover, when the UV cure according to the present invention is performed to the inter-layer insulation film 3 as one example of the improvement of mechanical strength, the modulus of elasticity increased from 8 GPa to 12 GPa, and therefore, it is confirmed that the mechanical strength improved by about 50%.

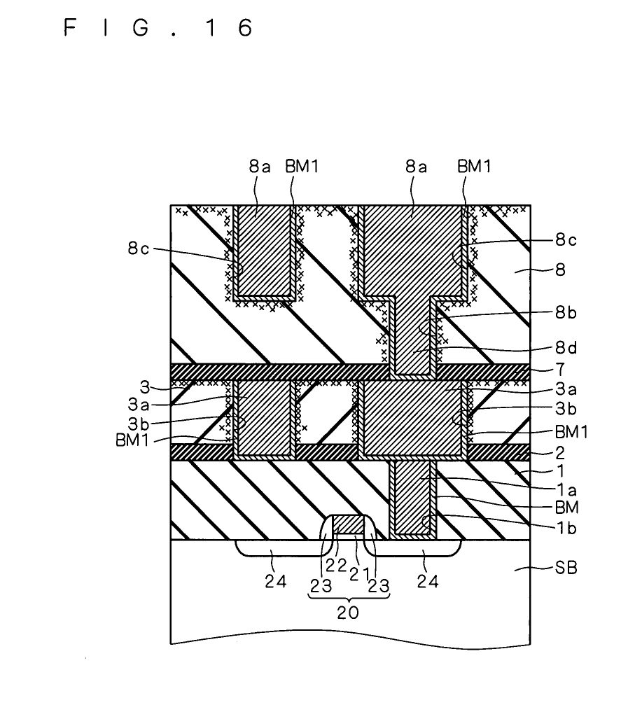

A differential spectrum of the FT-IR spectrum in the case of changing the oxygen concentration in the range of 25 ppm to 100 ppm is shown in FIG. 15 with a differential spectrum of the FT-IR spectrum in the case that the oxygen concentration is almost zero (0 ppm).

In FIG. 15, the wave number (cm⁻¹) is shown in the x-axis, the absorption intensity of the infrared light (an arbitrary unit) is shown in the y-axis, and a differential spectrum is shown in the case that the oxygen concentration is 25 ppm, 50 ppm, and 100 ppm. Moreover, each differential spectrum in FIG. 15 has the origin. However, illustration of the origin is omitted in the figure.

In FIG. 15, it is understood that the network of Si—O bonds can be increased without producing the 3-membered ring Si—O bond and the Si—H bond in a broad range of the oxygen concentration of 25 ppm to 100 ppm compared with the case of the oxygen concentration of 0 ppm.

Moreover, in FIG. 13 and FIG. 15, the Si—H bond is not detected in the case of introducing oxygen nor is it detected in the FT-IR spectrum. This means that the concentration of hydrogen in the SiOC film in the case of applying the Lw cure process according to the present invention is less than 1×10²⁰ atoms/cc which is a detection limit of hydrogen in the FT-IR method.

Moreover, although not shown in FIG. 15, it is confirmed that a differential spectrum having the above-described characteristic can be obtained even when the oxygen concentration is 10 ppm or less, and its lower limit is about 5 ppm which is a measurement limit of the oxygen concentration meter.

However, because a concentration of 5 ppm or less cannot be measured, there is a possibility that the above-described characteristics appear actually at 2 to 3 ppm.

Further, it is confirmed that the upper limit of the oxygen concentration in which the differential spectrum having the above-described characteristics can be obtained is 400 ppm.

Therefore, it can be said that the effect by the UV cure process according to the present invention can be given by setting the oxygen concentration in the UV chamber in the range of 5 ppm to 400 ppm.

### A-4. Modified Example 1

In the embodiment according to the present invention explained above, an example is shown in which the UV cure is performed by introducing a small amount of an oxygen gas in the chamber in which the UV cure is performed. However, the added gas is not limited to an oxygen gas, and the same effect can be obtained as long as it is a gas containing oxygen.

For example, the mechanical strength of the SiOC film can be improved without spoiling the process damage resistance with a gas generally used in semiconductor manufacturing such as a CO gas, a CO₂ gas, or an N₂O gas.

Further, in order to obtain the same effect as in the case of the oxygen gas with these gasses, a greater amount must be introduced. However, this becomes an advantage.

That is, in the case of the oxygen gas, the above-described effect can be obtained even with a concentration of 10 ppm or less. However, it is difficult to control the flow rate of the oxygen gas to achieve a concentration of 10 ppm or less in actuality because the concentration can be achieved with a small flow rate that is close to the lower limit of the flow rate control in the existing flow meter.

However, because a greater flow rate of the above-described gasses is needed than the oxygen gas in order to reach the same oxygen concentration, there are advantages that the flow rate control can be performed with good controllability even with the existing flow meter, and it is easy to handle.

Further, the above-described gasses containing oxygen may be used alone instead of an oxygen gas. However, they may be used by mixing with an oxygen gas.

Also in this case, because there is a necessity to increase the gas flow rate compared with the case of using only an oxygen gas, there are advantages that the flow rate control can be performed with good controllability even with the existing flow meter, and it is easy to handle.

### A-5. Modified Example 2

In the embodiment according to the present invention explained above, an example is shown in which an oxygen gas is introduced by adjusting the chamber in which the UV cure is performed to an atmospheric pressure or a little more positive pressure by nitrogen purge. However, the mechanical strength of the SiOC film can be improved without spoiling the process damage resistance by introducing a small amount of oxygen even in the case of performing the UV cure in a state that the pressure inside the chamber is reduced after introducing a gas such as nitrogen, helium, or argon.

### A-6. Modified Example 3

In the embodiment according to the present invention explained above, an example is shown in which the UV cure is performed by introducing a small amount of oxygen gas in the chamber in which the UV cure is performed. However, the same effect can be obtained by using oxygen remaining in the chamber and not introducing the oxygen gas actively.

That is, a deposition is generated on the inner wall of the chamber and the UV light irradiation window for the UV cure as a wafer process is performed. When the deposition increases, a trouble occurs in the UV cure, and therefore cleaning to remove the deposition is needed regularly.

This cleaning is an operation of performing the UV light irradiation while introducing an oxygen gas in the chamber that is in the state that a wafer is not loaded, and removing the deposition with ozone generated by the UV light irradiation, and this is performed before the UV cure process.

After finishing the cleaning, the oxygen gas is exhausted by nitrogen purge, and a wafer is loaded. However, oxygen remains in the chamber even after the nitrogen purge although it is in a small amount.

The remaining amount of the oxygen is about a few ppm to 10 ppm. However, the mechanical strength of the SiOC film can be improved without spoiling the process damage resistance with such an extremely small amount of the remaining oxygen.

Because oxygen has been conventionally considered to be harmful, oxygen has been made to be zero by a long-time nitrogen purge or vacuuming of the chamber after the cleaning is finished. However, in the case of adopting the above-described method, oxygen is made to remain in the chamber by reducing the nitrogen purge time or by not performing the vacuuming.

Further, not using the remaining gas of the oxygen gas used for the cleaning, the oxygen gas may be introduced in the chamber prior to the UV cure process, and then exhausted by the nitrogen purge, and a wafer is loaded.

Also in this case, the remaining amount of oxygen becomes about a few ppm to 10 ppm, and the mechanical strength of the SiOC film can be improved without spoiling the process damage resistance.

### A-7. Modified Example 4

In the embodiment according to the present invention explained above, an example is shown in which the UV cure process is performed on the semiconductor substrate SB right after the inter-layer insulation film 3 is formed (FIG. 3) and the semiconductor substrate SB right after the inter-layer insulation film 8 is formed (FIG. 7). However, the UV cure process may also be performed on the inter-layer insulation films 3 and 8 that are low-k films after the opening parts to be a wiring groove or a connection hole are formed.

Specifically, the UV cure process (the second curing) according to the present invention is performed on each of the surfaces of the low-k film exposed to inside the opening part 3b and the opening parts 8b and 8c in the steps shown in FIGS. 4 and 8.

That is, in the case of forming the opening part 3b and the opening parts 8b and 8c with dry-etching, the surface of the low-k films (the inter-layer insulation films 3 and 8) receive damage from the plasma used in the etching or the resist removal.

FIG. 16 is a figure schematically showing a damage layer of the surface of the low-k film formed by plasma used in the dry-etching or the resist removal in the semiconductor device 100.

The damage layer is represented with an X mark in FIG. 16, and it is understood that the damage layer is formed on the surface of the inter-layer insulation films 3 and 8 that become the inner face of the opening part 3b and the opening parts 8b and 8c and in the main face of the inter-layer insulation films 3 and 8, and that it is formed in the part of the inter-layer insulation films 3 and 8 exposed to plasma.

In this damage layer, the Si—CH₃ group included in the low-k film (the SiOC film in the embodiment) changes, a large amount of the Si—OH groups are produced, and it has come to the state of easily absorbing water from the atmosphere. It is necessary to remove such water as much as possible because it hinders the normal growth of the barrier metal and the Cu plating film to be formed on the top part of the low-k film.

The UV cure process of the present invention is also effective to the property modification of such damage layer, and the Si—OH group existing in the damage layer in a large amount can be changed to a network of Si—O bonds with a dehydration-condensation reaction.

Then, the network of Si—O bonds produced with the UV cure process according to the present invention have a strong process damage resistance from the cleaning step, for example, and the property modification of the damage layer can be performed more effectively.

While the invention has been shown and described in detail, the foregoing description is in all aspects illustrative and not restrictive. It is therefore understood that numerous modifications and variations can be devised without departing from the scope of the invention.

What is claimed is:

1. A manufacturing method of a semiconductor device having at least one layer of an SiOC film as an inter-layer insulation film, comprising the step of
(a) performing a first curing by irradiation with ultraviolet rays to said SiOC film after formation of said SiOC film, wherein
said first curing is performed in a condition that oxygen is included so that the oxygen concentration is 5 ppm to 400 ppm in the atmosphere of a chamber in which said first curing is performed.

2. The manufacturing method of a semiconductor device according to claim 1, wherein said step (a) includes a step of performing said first curing with said oxygen concentration being 25 ppm to 100 ppm.

3. The manufacturing method of a semiconductor device according to claim 1, wherein said step (a) includes a step of introducing an oxygen gas while controlling the flow rate into said chamber.

4. The manufacturing method of a semiconductor device according to claim 1, wherein said step (a) includes a step of introducing a gas selected from a group consisting of a CO gas, a CO₂ gas, an N₂O gas, an oxygen gas, and a combination of these gases.

5. The manufacturing method of a semiconductor device according to claim 1 comprising
a cleaning step of cleaning inside of said chamber by introducing an oxygen gas in said chamber and performing irradiation of ultraviolet rays prior to said step (a), wherein
said step (a) includes a step of exhausting said oxygen gas in said chamber so that said oxygen gas remains in said chamber at a concentration of 5 ppm to 10 ppm.

6. The manufacturing method of a semiconductor device according to claim 1 comprising
a step of introducing an oxygen gas into said chamber prior to the step (a), wherein
said step (a) includes a step of exhausting said oxygen gas in said chamber so that said oxygen gas remains in said chamber at a concentration of 5 ppm to 10 ppm.

7. The manufacturing method of a semiconductor device according to claim 1, wherein said step (a) performs said first curing by introducing a gas selected from a group consisting of nitrogen, helium, and argon in said chamber and reducing the pressure inside said chamber to an atmospheric pressure or lower.

8. The manufacturing method of a semiconductor device in claim 1, comprising a steps of
(b) forming an opening part on said SiOC film with dry-etching and
(c) performing a second curing by irradiation of ultraviolet rays to said SiOC film in which said opening part is formed, wherein
said second curing is performed in a condition that oxygen is included so that the oxygen concentration is 5 ppm to 400 ppm in the atmosphere of a chamber in which said second curing is performed.

9. A semiconductor device having at least one layer of an SiOC film as an inter-layer insulation film, wherein the concentration of hydrogen in the SiOC film is less than 1×10²⁰ atoms/cc.

10. The semiconductor device according to claim 9, wherein said SiOC film is formed by performing a first curing by irradiation with ultraviolet rays and
said first curing is performed in a condition that oxygen is included so that the oxygen concentration is 5 ppm to 400 ppm in the atmosphere of a chamber in which said first curing is performed.
